(19) United States
(12) Patent Application Publication
(10) Pub. No.: US 2006/0022195 A1
(43) Pub. Date: Feb. 2, 2006

(54) SCRIBE LINE STRUCTURE

(76) Inventor: Kun-Chih Wang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/710,761

(22) Filed: Aug. 1, 2004

(51) Int. Cl. H01L 23/58

(52) U.S. Cl. 257/48

(57) ABSTRACT

The present invention provides a scribe line structure, which includes a substrate, a plurality of dielectric layers of low dielectric constant materials formed on the substrate, at least a process monitor pattern made of materials of metal formed between the dielectric layers, and a dummy metal structure connected to the process monitor pattern. The dummy metal structure includes a plurality of dummy metal layers and a plurality of dummy vias. The dummy metal structure is formed on the surface of the substrate and is exposed in the region of the scribe line, thus facilitating heat dissipation and energy release from the scribe line structure.

### BACKGROUND OF INVENTION

1. Field of the Invention

The invention relates to a scribe line structure, and more particularly, to a scribe line structure, which utilizes a dummy metal structure to connect with process monitor patterns among a plurality of dielectric layers made out of low dielectric constant materials.

2. Description of the Prior Art

The manufacturing flow of the integrated circuit can be mainly distinguish into three stages as follows: (1) the manufacturing of the wafer, (2) the fabrication of the integrated circuit, and (3) the cutting, electric testing, sorting, and packaging of the integrated circuit. When fabricating the integrated circuit on the wafer, the whole wafer is divided uniformly into many overlapping dies, and the adjacent dies are separated by a scribe line. The cutting step of the integrated circuit utilizes a cutter to cut the wafer into individual dies along the scribe lines.

In recent years, the high integration semiconductor process, with an inter-metal dielectric layer collocated by the dual damascene technology and the use of low dielectric materials, is the most popular metal interconnect technology to date. Due to the low resistance of copper, and the low dielectric material, the RC delay between the metal wires is greatly reduced. However, for achieving low dielectric property, many of low dielectric materials have loose, and weak mechanical strength structures, and are fragile. Therefore a chip crack often occurs from lateral cutting stress while performing wafer dicing. The chip crack causes high infant mortality in products, thereby reducing yield in subsequent electric test processes. In addition, moisture can permeate into the integrated circuit along the chip crack to corrode the metal wires and cause the integrated circuit to break down in reliability test processes. Therefore the laser cutting technology is widely promoted by industry. The laser cutting technology, which utilizes laser energy concentrating in the front cutting edge to produce extreme heat stress in a partial region, is mainly for thin fragile film materials. Since the front cutting edge can be regarded as the tip of a crack, the heat stress makes the front cutting edge extend forward and then the cut item separates automatically. So the laser cutting technology can improve chip crack issues.

Please refer to FIG. 1. FIG. 1 is a top view of a scribe line according to the prior art. The top and bottom sides in the scribe line region 10 are protection layers 12 for protecting the device region on these two sides of the scribe line region 10. For preventing the effective area on a wafer from being wasted, at least a process monitor pattern 14 is located in the scribe line region 10, and can, for example, be located in the dielectric layer 16 of low dielectric constant materials.

Please refer to FIG. 2. FIG. 2 is a section view along line n-n′ of the scribe line region 10 shown in FIG. 1. As shown in FIG. 2, a scribe line structure includes a substrate 18, a plurality of dielectric layers 16a, 16b, 16c, 16d, 16e, and 16f of low dielectric constant materials upon substrate 18, and a process monitor pattern 14 located between the dielectric layer 16c and 16d. Thereof, the process monitor pattern 14 includes test keys, feature dimension measuring elements, or alignment marks, and is usually made of metal materials. Furthermore, a protection layer 12 covering two sides of the scribe line region 10 is set on the surface of the top dielectric layer 16f.

It is easier for a process monitor pattern made of metal materials to absorb laser energy than for a plurality of dielectric layers of low dielectric constant materials. So the metal structure may change its phase from solid to liquid or gas when the energy accumulates quickly in the metal structure in the scribe line. So this will cause the energy not only to release from bottom to top, but will also cause lateral exploding, and make chip cracks, thereby influencing product yields seriously.

### SUMMARY OF INVENTION

It is therefore an objective of the claimed invention to provide a scribe line structure to prevent chip cracks by using laser cutting.

According to the objective of the claimed invention, the scribe line structure includes a substrate, a plurality of dielectric layers formed on the substrate surface, at least a process monitor pattern formed in the dielectric layers, and a dummy metal structure formed on the substrate. The process monitor pattern is a metal structure, which has a plurality of layers, and connects with a dummy metal structure, which is composed of a plurality of dummy metal layers and a plurality of dummy metal vias. The dummy metal structure is exposed in the scribe line region.

The claimed invention utilizes a dummy metal structure exposed in a scribe line region. Therefore, laser energy can be absorbed uniformly by the dummy metal structure when a laser beam cuts a wafer. A good heat and energy irradiative system prevents chip cracks due to lateral explosion, and raises the yield of integrated circuit chips.

### BRIEF DESCRIPTION OF DRAWINGS

FIG. 1 is a top view of a scribe line according to the prior art.

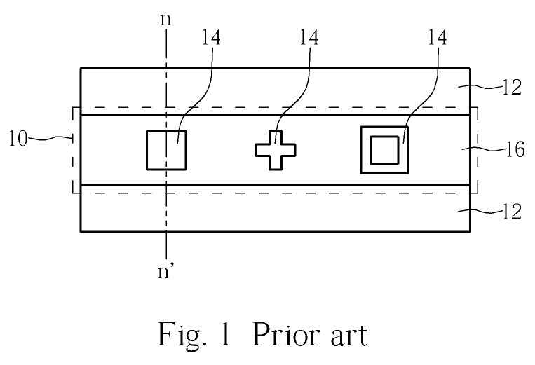

FIG. 2 is a section view along line n-n′ of the scribe line region shown in FIG. 1.

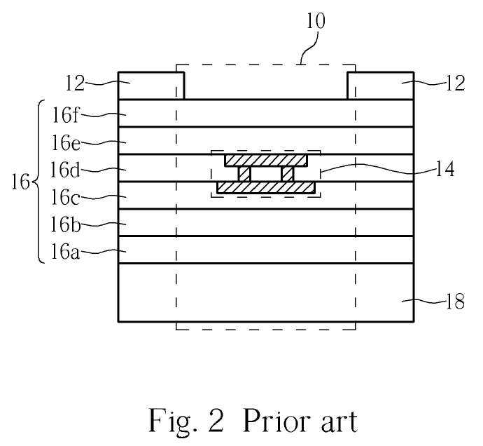

FIG. 3 is a section view of a first embodiment scribe line structure according to the present invention.

FIG. 4 is a section view of a second embodiment scribe line structure according to the present invention.

### DETAILED DESCRIPTION

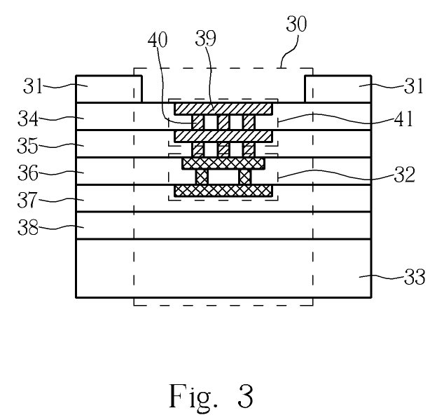

Please refer to FIG. 3. FIG. 3 is a section view of a first embodiment scribe line structure according to the present invention. As shown in FIG. 3, the bottom of the scribe line structure is a substrate 33 and a plurality of dielectric layers 34, 35, 36, 37, and 38 are formed on the substrate 33. Some of these dielectric layers 34-38 are dielectric layers having a dielectric constant less than or equal to 3 and some of them are made of other dielectric materials. Otherwise, these dielectric layers 34-38 can all be dielectric layers of low dielectric constant materials. A protection layer 31 is set on the surface of the top dielectric layer 34 and includes an open area to define a scribe line region 30.

The protection layer 31 is used to cover device regions on two sides of the scribe line region 30. The scribe line region 30 includes at least a process monitor pattern 32 made of metal material set between the dielectric layers 36 and 37. The process monitor pattern 32 includes test keys, feature dimension measuring elements, or alignment marks, and the top of the process monitor pattern 32 connects a dummy metal structure 41. The dummy metal structure 41 depending on the need can be composed of different sizes and quantities of the dummy metal layer 39 and the dummy metal vias 40, and is exposed in the scribe line region 30. According to a preferred embodiment of the present invention, these dummy metal vias 40 link each dummy metal layer 39 to create a heat irradiative system, which can release heat and energy produced in the cutting or other heat process from the surface of the scribe line region 30 to protect semiconductor devices on the chip. However, according to other embodiments of the present invention, these dummy metal vias can penetrate the dielectric layers 34 and 35 immediately and connect with the process monitor pattern 32 without making the dummy metal layer 39. In addition, according to other embodiments of the present invention, the dummy metal structure 41 is not constricted to being set above the process monitor pattern 32. If there are two or more process monitor patterns 32, the dummy metal structure 41 can be connected between these process monitor patterns 32 and the top of the dummy metal structure 41 should be exposed in the scribe line region 30.

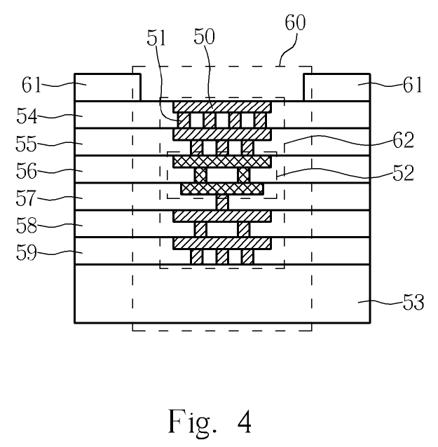

Please refer to FIG. 4. FIG. 4 is a section view of second embodiment scribe line structure according to the present invention. The difference between the first and second embodiments is that dummy metal structure is formed above the process monitor pattern and exposed in the scribe line region according to the first embodiment, and heat and energy can be released effectively from the surface of the scribe line region. However, according to the second embodiment of the present invention, a dummy metal structure passes through dielectric layers until the surface of the substrate connects with process monitor pattern and is exposed in the scribe line region. Therefore, in the wafer dicing process, laser energy can be absorbed more uniformly, and heat and energy can be released effectively to the top and bottom to protect semiconductor devices on chips and prevent chip cracks due to lateral explosion.

As shown in FIG. 4, the bottom of the scribe line structure is a substrate 53, and a plurality of dielectric layers 54, 55, 56, 57, 58, and 59 are formed on the surface of the substrate 53. Some of these dielectric layers 54-59 are dielectric layers having a dielectric constant less than or equal to 3 and some of them are made of other dielectric materials. Otherwise, these dielectric layers 54-59 can all be dielectric layers of low dielectric constant materials. A protection layer 61 is set on the surface of the top dielectric layer 54 and includes an open area to define a scribe line region 60.

The protection layer 61 is used to cover device regions on two sides of the scribe line region 60. The scribe line region 60 includes at least a process monitor pattern 52 made of metal material set between the dielectric layer 56 and 57. The process monitor pattern 52 connects a dummy metal structure 62 to create a passageway for heat and energy release. The dummy metal structure 62 depending on the need can be composed of different sizes and quantities of the dummy metal layer 50 and dummy metal vias 51. The dummy metal structure 62 is formed on the substrate 53 and is exposed in the scribe line region 60. Heat and energy, produced in the cutting or other heat process, can be released effectively from the surface of the scribe line region 60 or the substrate 53 to protect semiconductor devices on the chip. However, according to other embodiments of the present invention, the dummy metal via 51 can penetrate the dielectric layers 54, 55, 57, 58, and 59 immediately and connect the process monitor pattern 52 without making the dummy metal layer 50.

In contrast to the prior art, the scribe line structure of the present invention has a dummy metal structure. Therefore, in wafer dicing, heat and energy can be released effectively from the surface of a scribe line region to prevent chip cracks due to lateral explosion, and raises the yield of integrated circuit chips.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A scribe line structure, comprising:
a substrate;
a plurality of dielectric layers formed on the surface of the substrate comprising at least a process monitor pattern set in a scribe line region; and
a dummy metal structure formed on the surface of the substrate connecting with the process monitor pattern and exposed in the scribe line region.

2. The scribe line structure of claim 1 wherein the plurality of dielectric layers comprise dielectric layers having a dielectric constant less than or equal to 3.

3. The scribe line structure of claim 1 wherein the dummy metal structure comprises a plurality of dummy vias.

4. The scribe line structure of claim 1 wherein the dummy metal structure comprises a plurality of dummy metal layers.

5. The scribe line structure of claim 1 wherein the process monitor pattern is made of metal materials.

6. The scribe line structure of claim 1 wherein the process monitor pattern comprises test keys, feature dimension measuring elements, or alignment marks.

7. The scribe line structure of claim 1 wherein the surface of the substrate further comprises a protective layer covering two sides of the surface of dielectric within the scribe line region.

8. A scribe line structure, comprising:
a substrate, the surface of the substrate comprising at least a scribe line region;
a plurality of dielectric layers formed on the surface of the substrate comprising at least a process monitor pattern set in the scribe line region; and
a heat irradiative structure formed in the plurality of dielectric layers connecting the plurality of dielectric layers with the surface of the substrate and exposed in the scribe line region.

9. The scribe line structure of claim 8 wherein the plurality of dielectric layers comprise dielectric layers having a dielectric constant less than or equal to 3.

10. The scribe line structure of claim 8 wherein the heat irradiative structure is a dummy metal structure.

11. The scribe line structure of claim 10 wherein the dummy metal structure comprises a plurality of dummy vias.

12. The scribe line structure of claim 10 wherein the dummy metal structure comprises a plurality of dummy metal layers.

13. The scribe line structure of claim 8 wherein the heat irradiative structure connects with the process monitor pattern.

14. The scribe line structure of claim 8 wherein the process monitor pattern is made of metal materials.

15. The scribe line structure of claim 8 wherein the process monitor pattern comprises test keys, feature dimension measuring elements, or alignment marks.

16. The scribe line structure of claim 8 wherein the surface of the substrate further comprises a protective layer covering two sides of the surface of dielectric surface within the scribe line region.
